(19) United States
(12) Patent Application Publication
(10) Pub. No.: US 2015/0195902 A1
(43) Pub. Date: Jul. 9, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Eung Suek LEE, Suwon-Si (KR); Hyo Seung NAM, Suwon-Si (KR); Sung Uk LEE, Suwon-Si (KR); Jae Hoon CHOI, Suwon-si (KR); II Jong SEO, Suwon-Si (KR); Yong Ho BAEK, Suwon-Si (KR)

(73) Assignee: SAMSUNG ELECTRO-MECHANICS CO., LTD., Suwon-Si (KR)

(21) Appl. No.: 14/592,696

(22) Filed: Jan. 8, 2015

(30) Foreign Application Priority Data
Jan. 9, 2014 (KR) 10-2014-0002974

(51) Int. Cl. H05K 1/02; H05K 3/00; C23C 14/34; H05K 1/09

(52) U.S. Cl. CPC H05K 1/0284; H05K 1/0298; H05K 1/09; H05K 3/007; C23C 14/34

(57) ABSTRACT

There are provided a printed circuit board and a method of manufacturing the same. The printed circuit board according to an exemplary embodiment of the present disclosure includes: an insulating layer; a first circuit buried below the insulating layer and having a lower surface formed to be exposed from a lower surface of the insulating layer; a second circuit layer formed on the insulating layer; and a first solder resist layer formed below the insulating layer and the first circuit layer and formed to expose a portion of the first circuit layer.

### CROSS-REFERENCE TO RELATED APPLICATION

This application claims the foreign priority benefit of Korean Patent Application No. 10-2014-0002974, filed on Jan. 9, 2014, entitled “Printed Circuit Board and Method of Manufacturing the Same” which is hereby incorporated by reference in its entirety into this application.

### BACKGROUND

Embodiments of the present disclosure relate to a printed circuit board and a method of manufacturing the same.

Recently, a trend toward multi-functionalization and a speed increase of electronic products has rapidly progressed. In accordance with this trend, a semiconductor chip and a printed circuit board on which the semiconductor chip is mounted have also been developed at a very rapid speed. In the printed circuit board as described above, thinness and lightness, fine circuit implementation, excellent electrical characteristics, high reliability, a high speed signal transfer, and the like, are demanded.

Meanwhile, according to the related art, a core substrate preventing a warpage phenomenon of the printed circuit board by inserting a core layer thereinto has been mainly used. However, the core substrate had problems such as a thick thickness and a long signal processing time. Accordingly, in order to cope with the thinness according to the development of the printed circuit board, a coreless substrate capable of decreasing the entire thickness and reducing the signal processing time by removing the core substrate has been spotlighted.

### RELATED ART DOCUMENT

### Patent Document

(Patent Document 1) US Patent Application Publication No. 20040058136

### SUMMARY

An aspect of the present disclosure may provide a printed circuit board capable of preventing a bridge phenomenon from being generated when a conductive bump is formed, and a method of manufacturing the same.

According to an aspect of the present disclosure, a printed circuit board may include: an insulating layer; a first circuit buried below the insulating layer and having a lower surface formed to be exposed from a lower surface of the insulating layer; a second circuit layer formed on the insulating layer; and a first solder resist layer formed below the insulating layer and the first circuit layer and formed to expose a portion of the first circuit layer.

The first circuit layer may include a seed layer and a metal layer formed on the seed layer, and the seed layer may have a lower surface exposed from the insulating layer.

The seed layer may include at least one of titanium (Ti), cobalt (co), and nickel (Ni).

The seed layer may be a mixture of at least one of titanium (Ti), cobalt (co), and nickel (Ni), and copper (Cu).

The second circuit layer may have a shape protruded from an upper surface of the insulating layer.

The insulating layer may further include an internal circuit layer formed between the first circuit layer and the second circuit layer and formed in one or more layers.

The printed circuit board may further include a second solder resist layer formed on the insulating layer and the second circuit, and formed to expose a portion of the second circuit layer.

According to another aspect of the present disclosure, a method of manufacturing a printed circuit board may include: preparing a carrier member; forming a bonding layer on the carrier member; forming a first solder resist layer on the bonding layer; forming a seed layer on the first solder resist layer; forming a patterned metal layer on the seed layer; forming a circuit layer including the metal layer and the seed layer by removing the seed layer exposed by the metal layer; an insulating layer formed on the first solder resist layer and burying the first circuit layer; forming a second circuit layer on the insulating layer; removing the carrier member and the bonding layer; and patterning the first solder resist layer to expose a portion of the first circuit layer.

The bonding layer may be formed by a sputtering method.

The bonding layer may include at least one of titanium (Ti), cobalt (co), and nickel (Ni).

The bonding layer may be a mixture of at least one of titanium (Ti), cobalt (co), and nickel (Ni), and copper (Cu).

The seed layer may be formed by a sputtering method.

The seed layer may include at least one of titanium (Ti), cobalt (co), and nickel (Ni).

The seed layer may be a mixture of at least one of titanium (Ti), cobalt (co), and nickel (Ni), and copper (Cu).

In the forming of the second circuit layer, the second circuit layer may be protruded from an upper surface of the insulating layer.

The method may further include, before the forming of the second circuit layer, forming an internal circuit layer of one or more layers in the insulating layer.

The method may further include, after the forming of the second circuit layer, forming a second solder resist layer formed on the insulating layer and the second circuit layer.

The method may further include, after the forming of the second solder resist layer, patterning the second solder resist layer to expose a portion of the second circuit layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustration view showing a printed circuit board according to an exemplary embodiment of the present disclosure; and

FIGS. 2 to 19 are views showing a method of manufacturing a printed circuit board according to an exemplary embodiment of the present disclosure.

### DETAILED DESCRIPTION

The aspects, features and advantages of the present invention will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

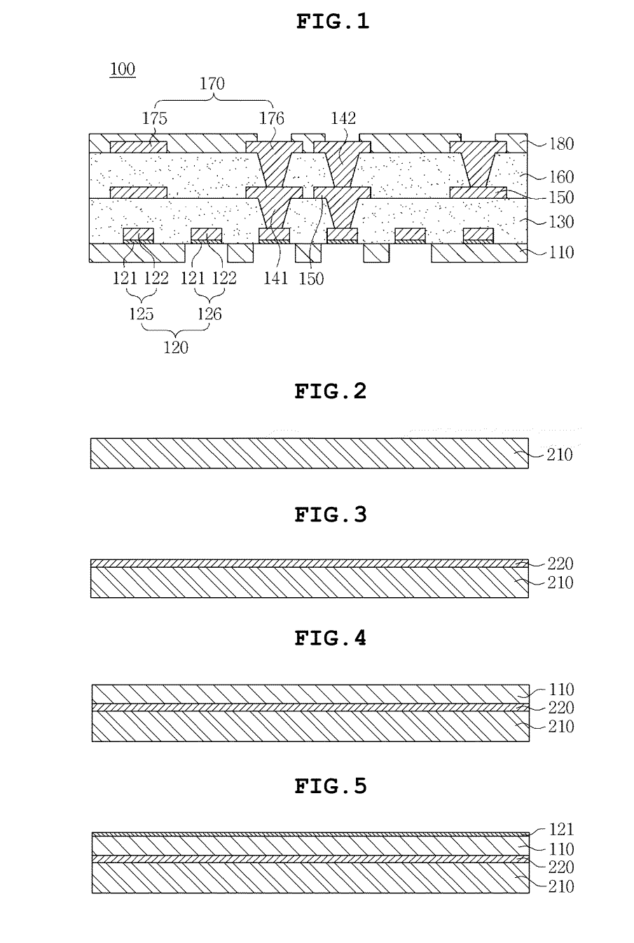

FIG. 1 is an illustration view showing a printed circuit board according to an exemplary embodiment of the present disclosure.

Referring to FIG. 1, a printed circuit board 100 may include a first insulating layer 130, a second insulating layer 160, a first circuit layer 120, a second circuit layer 170, a first solder resist layer 110, and a second solder resist layer 180.

The first insulating layer 130 and the second insulating layer 160 according to an exemplary embodiment of the present disclosure may be typically formed of a complex polymer resin used as an interlayer insulating material. For example, the first insulating layer 130 and the second insulating layer 160 may be formed of a prepreg, Ajinomoto Build up Film (ABF), and an epoxy based resin such as FR-4, Bismaleimide Triazine (BT), or the like. However, in an exemplary embodiment of the present disclosure, a material of the first insulating layer 130 and the second insulating layer 160 are not limited thereto.

According to an exemplary embodiment of the present disclosure, the second insulating layer 160 may be formed on the first insulating layer 130.

According to an exemplary embodiment of the present disclosure, the first circuit layer 120 may be formed to be buried below the first insulating layer 130. Since the first circuit layer 120 is formed to be buried in the first insulating layer 130, such that the first circuit layer 120 may be finely or densely formed. That is, since the first circuit layer 120 is buried in the first insulating layer 130, sufficient insulation between adjacent patterns may be achieved even though the patterns are finely or densely formed. The first circuit layer 120 according to an exemplary embodiment of the present disclosure may have a lower surface formed to be exposed from a lower surface of the first insulating layer 130.

According to an exemplary embodiment of the present disclosure, the first circuit layer 120 may include a seed layer 121 and a metal layer 122 formed on the seed layer 121. As a result, the lower surface of the first circuit layer 120 exposed from the first insulating layer 130 may become the seed layer 121.

According to an exemplary embodiment of the present disclosure, the seed layer 121 may be formed of a conductive material. The seed layer according to an exemplary embodiment of the present disclosure may include at least one of titanium (Ti), cobalt (co), and nickel (Ni). For example, the seed layer may be formed of a single material such as titanium (Ti), cobalt (co), nickel (Ni), or the like. Alternatively, the seed layer may be formed of a mixed material in which at least two of titanium (Ti), cobalt (co), and nickel are mixed. Alternatively, the seed layer may be formed of a single material formed of titanium (Ti), cobalt (co), and nickel, or a mixed material in which copper is mixed in the mixed material.

According to an exemplary embodiment of the present disclosure, the metal layer 122 may be formed of a conductive material. For example, the metal layer 122 may be formed of copper. However, a material of the metal layer 122 is not limited to copper and any material among conductive materials for a circuit which are used in a field of circuit board may be used.

The first circuit layer 120 according to an exemplary embodiment of the present disclosure may include a first circuit pattern 125 and a first external connection pad 126. The first external connection pad 126 may be electrically connected to an external component (not shown) through a connection member such as a conductive bump, a conductive ball, a wire, or the like.

According to an exemplary embodiment of the present disclosure, an internal circuit layer 150 may be formed on the first insulating layer 130. The internal circuit layer 150 may be electrically connected to the first circuit layer 120 through a first via 141. Alternatively, the internal circuit layer 150 may be electrically connected to the second circuit layer 170 through a second via 142. Although an exemplary embodiment of the present disclosure describes that the internal circuit layer 150 is configured in one-layer by way of example, the present disclosure is not limited thereto. For example, the internal circuit layer 150 may be formed in a multi-layer of two layers or more. In the case in which the internal circuit layer 150 is formed in the multi-layer, internal vias (not shown) which electrically connect the respective layers of the internal circuit layer 150 to each other may be further formed. Alternatively, the internal circuit layer 150 may be omitted. In the case in which the internal circuit layer 150 is not formed, a first via 141 and a second via 142 may be omitted. Alternately, in the case in which the internal circuit layer 150 is not formed, only one of the first via 141 and the second via 142 may be formed so as to electrically connect the first circuit layer 120 and the second circuit layer 170 to each other.

According to an exemplary embodiment of the present disclosure, the second circuit layer 170 may be formed on the second insulating layer 160. As shown in FIG. 1, the second circuit layer 170 may be formed to be protruded from an upper surface of the second insulating layer 160. The second circuit layer 170 according to an exemplary embodiment of the present disclosure may include a second circuit pattern 175 and a second external connection pad 176. The second external connection pad 176 may be electrically connected to an external component (not shown) through a connection member such as a conductive bump, a conductive ball, a wire, or the like.

According to an exemplary embodiment of the present disclosure, the second circuit layer 170 may be formed of a conductive material. For example, the second circuit layer 170 may be formed of copper. However, a material of the second circuit layer 170 is not limited to copper and any material among conductive materials for a circuit which are used in a field of circuit board may be used.

According to an exemplary embodiment of the present disclosure, the first solder resist layer 110 may be formed below the first insulating layer 130. The first solder resist layer 110 may cover the first circuit layer 120 exposed from the first insulating layer 130 so as to protect the first circuit layer 120 from an external environment. In this case, the first solder resist layer 110 may be patterned to expose a portion of the first circuit layer 120. For example, the first solder resist layer 110 may be patterned to cover the first circuit pattern 125 and expose the first external connection pad 126.

The first solder resist layer 110 formed as described above may prevent a solder from being applied to the first circuit pattern 125 when a soldering is performed on the printed circuit board 100. In addition, the first solder resist layer 110 may prevent the first circuit pattern 125 from being oxidized.

According to an exemplary embodiment of the present disclosure, the first circuit layer 120 may be formed to be buried in the first insulating layer 130 and the first solder resist layer 110 may be formed to be protruded from the first insulating layer 130. As a result, the first circuit layer 120 and the first solder resist layer 110 may be formed in a step shape.

According to the related art, when the conductive bumps are formed on the first external connection pad 126, a bridge phenomenon in which the adjacent conductive bumps contact with each other may be generated. The first solder resist layer 110 according to an exemplary embodiment of the present disclosure may be formed to be more protruded than the first circuit layer 120 to serve as a barrier. Accordingly, when the conductive bumps are formed on the first external connection pad 126, the generation of the bridge phenomenon may be prevented by the step shape of the first circuit layer 120 and the first solder resist layer 110.

The second solder resist layer 180 according to an exemplary embodiment of the present disclosure may be formed on the second insulating layer 160. The second solder resist layer 180 may cover the second circuit layer 170 formed on the second insulating layer 160 so as to protect the second circuit layer 170 from an external environment. In this case, the second solder resist layer 180 may be patterned to expose a portion of the first circuit layer 170. For example, the second solder resist layer 180 may be patterned to cover the second circuit pattern 175 and expose the second external connection pad 176. The second solder resist layer 180 formed as describe above may prevent a solder from being applied to the second circuit pattern 175 when being soldered or prevent the second circuit pattern 175 from being oxidized.

In addition, the second solder resist layer 180 and the second external connection pad 176 may be formed in a step shape. As a result, when the conductive bumps are formed on the second external connection pad 176, the generation of the bridge phenomenon may be prevented.

The first solder resist layer 110 and the second solder resist layer 180 according to an exemplary embodiment of the present disclosure may be formed of a heat-resistant covering material.

In an exemplary embodiment of the present disclosure, the insulating layer has been described by classifying it into the first insulating layer 130 and the second insulating layer 160 for convenience of explanation. However, in the case in which the first insulating layer 130 and the second insulating layer 160 are formed of the same material, a structure in which the first circuit layer 120 and the second circuit layer 170 are formed in a single insulating layer may be formed.

FIGS. 2 to 19 are views showing a method of manufacturing a printed circuit board according to an exemplary embodiment of the present disclosure.

Referring to FIG. 2, a carrier member 210 may be prepared.

The carrier member 210 according to an exemplary embodiment of the present disclosure may be formed of an insulating material. As the insulating material, a resin insulating material may be used. The resin insulating material may be a thermosetting resin such as an epoxy resin, or a thermoplastic resin such as polyimide. Alternatively, as the resin insulating material, a prepreg in which a reinforcing material is impregnated in the thermosetting resin or the thermoplastic resin may be used. For example, the reinforcing material may be a glass fiber or an inorganic filler. Alternatively, the resin insulating layer may be a photocurable resin. The insulating material of the carrier member 210 has been described, but it is not limited thereto.

Alternatively, the carrier member 210 may have a laminated plate structure in which a metal member (not shown) is formed on one surface or both surfaces of the insulating material. In this case, the carrier member 210 may further include a mold release agent (not shown) between the insulating material and the metal member (not shown) in order to more easily separate the carrier member 210 from a printed circuit board (not shown) which is to be formed later.

Referring to FIG. 3, a bonding layer 220 may be formed.

According to an exemplary embodiment of the present disclosure, the bonding layer 220 may be formed on the carrier member 210. The bonding layer 220 according to an exemplary embodiment of the present disclosure may be formed to improve adhesion between the carrier member 210 and a first solder resist layer (not shown) which is to be formed later.

According to an exemplary embodiment of the present disclosure, the bonding layer 220 may be formed by a sputtering method to secure adhesion with the carrier member 210. The bonding layer 220 may be formed of a conductive material. The bonding layer 220 according to an exemplary embodiment of the present disclosure may include at least one of titanium (Ti), cobalt (co), and nickel (Ni). For example, the bonding layer 220 may be formed of a single material such as titanium (Ti), cobalt (co), nickel (Ni), or the like. Alternatively, the bonding layer 220 may be formed of a mixed material in which at least two of titanium (Ti), cobalt (co), and nickel are mixed. Alternatively, the bonding layer 220 may be formed of a single material formed of titanium (Ti), cobalt (co), and nickel, or a mixed material in which copper is mixed in the mixed material.

Referring to FIG. 4, a first solder resist layer 110 may be formed.

According to an exemplary embodiment of the present disclosure, the first solder resist layer 110 may be formed on the bonding layer 220. The first solder resist layer 110 may be laminated in a film state on the bonding layer 220. Alternatively, the first solder resist layer 110 may be printed in a liquid state on the on the bonding layer 220.

Referring to FIG. 5, a seed layer 121 may be formed.

According to an exemplary embodiment of the present disclosure, the seed layer 121 may be formed on the first solder resist layer 110. According to an exemplary embodiment of the present disclosure, the seed layer 121 may be formed by the sputtering method in order to secure adhesion with the first solder resist layer 110. The seed layer 121 may be formed of a conductive material. The seed layer according to an exemplary embodiment of the present disclosure may include at least one of titanium (Ti), cobalt (co), and nickel (Ni). For example, the seed layer may be formed of a single material such as titanium (Ti), cobalt (co), nickel (Ni), or the like. Alternatively, the seed layer may be formed of a mixed material in which at least two of titanium (Ti), cobalt (co), and nickel are mixed. Alternatively, the seed layer may be formed of a single material formed of titanium (Ti), cobalt (co), and nickel, or a mixed material in which copper is mixed in the mixed material.

The seed layer 121 formed as described above may serve as a lead line of an electro-plating, which in turn is performed to form a first circuit layer (not shown).

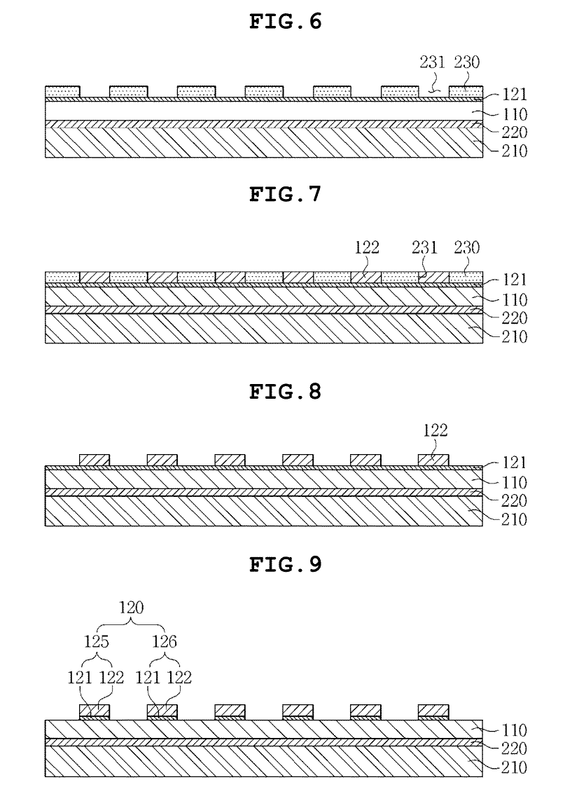

Referring to FIG. 6, a plating resist 230 may be formed.

According to an exemplary embodiment of the present disclosure, the plating resist 230 may be formed on the seed layer 121. The plating resist 230 may include an opening part 231 opening a region in which the first circuit layer (not shown) is to be formed. For example, the plating resist 230 may be formed of a photosensitive material such as a dry film. Accordingly, by forming the plating resist 230 on the seed layer 121 and then performing an exposure and development operation, the opening part 231 may be patterned. However, a material and a forming method of the plating resist 230 are not limited thereto.

Referring to FIG. 7, a metal layer 122 may be formed.

According to an exemplary embodiment of the present disclosure, the metal layer 122 may be formed on the seed layer 121 exposed by the plating resist 230. The metal layer 122 may be formed by performing the electro-plating on the opening part 231 of the plating resist 230. The metal layer 122 may be formed of a conductive material. For example, the metal layer 122 may be formed of copper (Cu). However, a material of the metal layer 122 is not limited to copper and may be selected among conductive materials for a circuit which are used in a field of circuit board.

According to an exemplary embodiment of the present disclosure, since the opening part 231 of the plating resist 230 is formed in a region in which the first circuit layer (not shown) is to be formed, the metal layer 122 may also be formed in the region in which the first circuit layer (not shown) is to be formed.

Referring to FIG. 8, a plating resist 230 (see FIG. 7) may be removed.

Referring to FIG. 9, a seed layer 121 may be removed.

According to an exemplary embodiment of the present disclosure, the seed layer 121 exposed to the outside by the removal of the plating resist 230 (see FIG. 7) may be removed. As a result, the seed layer below the metal layer 122 may not be removed and may remain. The seed layer 121 may be removed by any method of methods of removing a seed layer used in a field of circuit board.

As described above, the exposed seed layer 121 is removed, whereby the first circuit layer 120 may be formed. That is, according to an exemplary embodiment of the present disclosure, the first circuit layer 120 may be formed of the seed layer 121 and the metal layer 122 formed on the seed layer 121. The first circuit layer 120 according to an exemplary embodiment of the present disclosure may include a first circuit pattern 125 and a first external connection pad 126. The first external connection pad 126 may be electrically connected to an external component (not shown) through a connection member such as a conductive bump, a conductive ball, a wire, or the like.

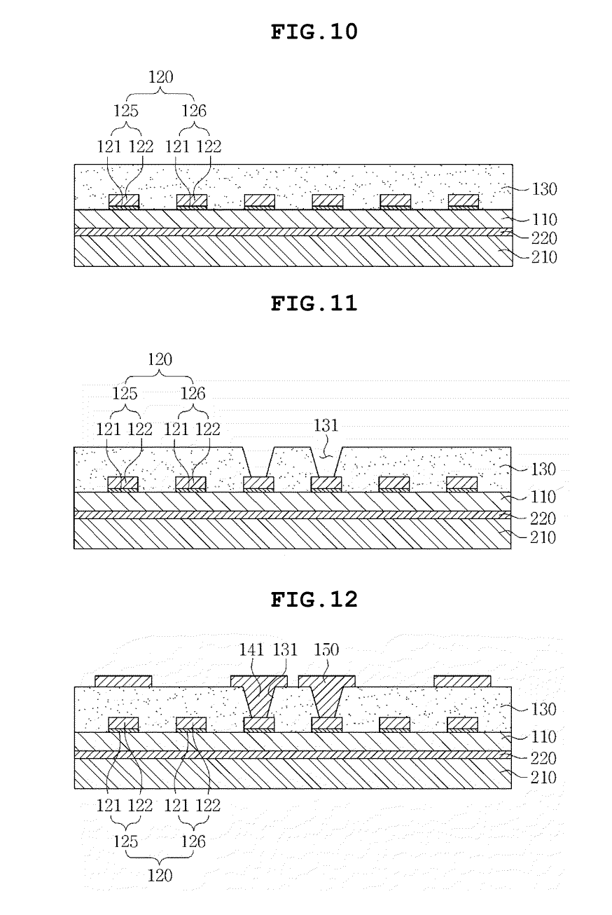

Referring to FIG. 10, a first insulating layer 130 may be formed.

According to an exemplary embodiment of the present disclosure, the first insulating layer 130 may be formed on the first solder resist layer 110. In this case, the first insulating layer 130 may be formed to bury the first circuit layer 120. Since the first circuit layer 120 is buried by the first insulating layer 130, sufficient insulation between adjacent patterns may be achieved even though the patterns of the first circuit layer 120 are finely or densely formed.

The first insulating layer 130 according to an exemplary embodiment of the present disclosure may be formed by being laminated in a film state on the first solder resist layer 110 and the first circuit layer 120. Alternatively, the first insulating layer 130 may be formed by being printed in a liquid state on the first solder resist layer 110 and the first circuit layer 120. The first insulating layer 130 according to an exemplary embodiment of the present disclosure may be formed by using a method of forming an insulating layer which is well known in a field of circuit board.

The first insulating layer 130 according to an exemplary embodiment of the present disclosure may be typically formed of a complex polymer resin used as an interlayer insulating material. For example, the first insulating layer 130 may be formed of a prepreg, Ajinomoto Build up Film (ABF), and an epoxy based resin such as FR-4, Bismaleimide Triazine (BT), or the like. However, in an exemplary embodiment of the present disclosure, a material of the first insulating layers 130 is not limited thereto.

Referring to FIG. 11, a first via hole 131 may be formed in the first insulating layer 130.

According to an exemplary embodiment of the present disclosure, the first via hole 131 may be formed to penetrate through the first insulating layer 130 to expose the first circuit layer 120. For example, the first via hole 131 may be formed by using a laser drill.

Referring to FIG. 12, a first via 141 and an internal circuit layer 150 may be formed.

According to an exemplary embodiment of the present disclosure, the first via 141 may be formed by filling the first via hole 131 with a conductive material. In addition, the internal circuit layer 150 may be formed on the first insulating layer 130. The internal circuit layer 150 may be formed simultaneously with the first via 141 or may be formed after the first via 141 is formed. The internal circuit layer 150 may be formed of a conductive material.

According to an exemplary embodiment of the present disclosure, the materials of both of the first via 141 and the internal circuit layer 150 may be used without limit as long as they are the conductive materials for the circuit. In addition, the first via 141 and the internal circuit layer 150 may be formed by using, without limit, any method among methods of forming a via and a circuit layer used in the field of circuit board.

Although an exemplary embodiment of the present disclosure describes that the internal circuit layer 150 is formed in one-layer by way of example, the present disclosure is not limited thereto. For example, the internal circuit layer 150 may be formed in a multi-layer of two layers or more. In the case in which the internal circuit layer 150 is formed in the multi-layer, internal vias (not shown) which electrically connect the respective layers to each other may also be further formed. In addition, an internal insulating layer (not shown) for insulating between the respective layers of the internal circuit layer 150 may be further formed. The internal circuit layer 150, the internal via (not shown), and the internal insulating layer (not shown) which have the multi-layer structure as described above may be formed by a typical method of forming the circuit layer, the via, and the insulating layer in the field of circuit board.

Alternatively, the operation of forming the internal circuit layer 150 may be omitted.

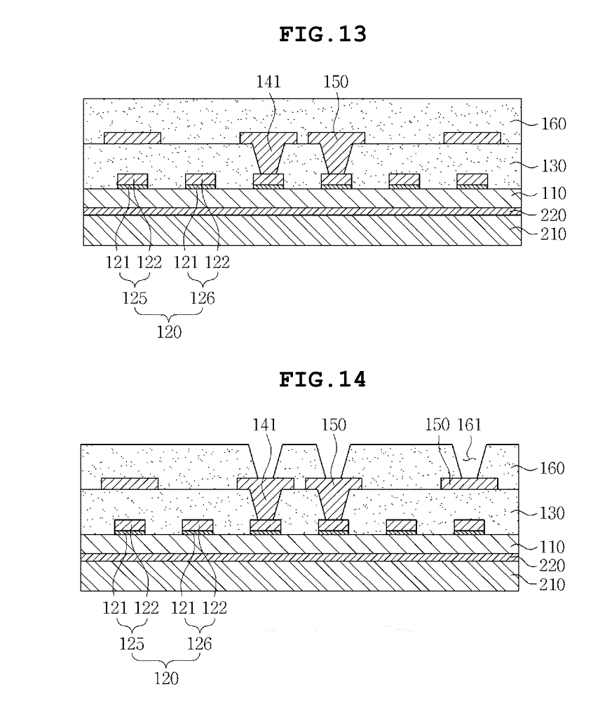

Referring to FIG. 13, a second insulating layer 160 may be formed.

According to an exemplary embodiment of the present disclosure, the second insulating layer 160 may be formed on the first insulating layer 130. In this case, the second circuit layer 170 may be formed to bury the internal circuit layer 150.

The second insulating layer 160 according to an exemplary embodiment of the present disclosure may be formed by being laminated in a film state on the first insulating layer 130 and the internal circuit layer 150. Alternatively, the second insulating layer 130 may be formed by being printed in a liquid state on the first insulating layer 130 and the internal circuit layer 150. The second insulating layer 160 according to an exemplary embodiment of the present disclosure may be formed by using a method of forming an insulating layer which is well known in a field of circuit board.

The second insulating layer 160 according to an exemplary embodiment of the present disclosure may be typically formed of a complex polymer resin used as an interlayer insulating material. For example, the second insulating layer 160 may be formed of a prepreg, Ajinomoto Build up Film (ABF), and an epoxy based resin such as FR-4, Bismaleimide Triazine (BT), or the like. However, in an exemplary embodiment of the present disclosure, a material of the second insulating layers 160 is not limited thereto.

Referring to FIG. 14, a second via hole 161 may be formed.

According to an exemplary embodiment of the present disclosure, the second via hole 161 may be formed to penetrate through the second insulating layer 160 to expose the internal circuit layer 150. For example, the second via hole 161 may be formed by using a laser drill.

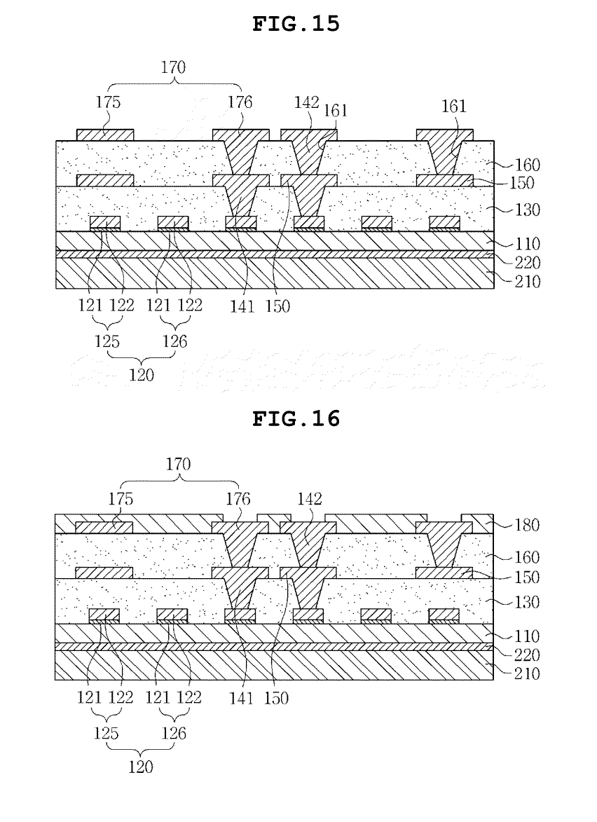

Referring to FIG. 15, a second via 142 and a second circuit layer 170 may be formed.

According to an exemplary embodiment of the present disclosure, the second via 142 may be formed by filling the second via hole 161 with a conductive material. In addition, the second circuit layer 170 may be formed on the second insulating layer 160. The second circuit layer 170 may be formed simultaneously with the second via 142 or may be formed after the second via 142 is formed. The second circuit layer 170 may be formed of a conductive material.

According to an exemplary embodiment of the present disclosure, the materials of both of the second via 142 and the second circuit layer 170 may be used without limit as long as they are the conductive materials for the circuit. In addition, the second via 142 and the second circuit layer 170 may be formed by using, without limit, any method among methods of forming a via and a circuit layer used in the field of circuit board.

If the formation of the internal circuit layer 150 is omitted in FIG. 12, the formation of the second via 142 may also be omitted. That is, the first via 141 formed in FIG. 12 may be formed to electrically connect the first circuit layer 120 and the second circuit layer 170 to each other. This may be easily changed according to selection of those skilled in the art.

The second circuit layer 170 according to an exemplary embodiment of the present disclosure may be formed to be protruded from an upper surface of the second insulating layer 160. The second circuit layer 170 according to an exemplary embodiment of the present disclosure may include a second circuit pattern 175 and a second external connection pad 176. The second external connection pad 176 may be electrically connected to an external component (not shown) through a connection member such as a conductive bump, a conductive ball, a wire, or the like.

In an exemplary embodiment of the present disclosure, the insulating layer has been described by classifying it into the first insulating layer 130 and the second insulating layer 160 for convenience of explanation. However, in the case in which the first insulating layer 130 and the second insulating layer 160 are formed of the same material, a structure in which the first circuit layer 120 and the second circuit layer 170 are formed in a single insulating layer may be formed.

Referring to FIG. 16, a second solder resist layer 180 may be formed.

According to an exemplary embodiment of the present disclosure, the second solder resist layer 180 may be formed on the second insulating layer 160. In addition, the second solder resist layer 180 may be formed to cover the second circuit layer 170 and formed to protect the second circuit layer 170 from an external environment. In this case, the second solder resist layer 180 may be patterned to expose a portion of the second circuit layer 170. For example, the second solder resist layer 180 may be patterned to cover the second circuit pattern 175 and expose the second external connection pad 176. The second solder resist layer 180 formed as describe above may prevent a solder from being applied to the second circuit pattern 175 when being soldered or prevent the second circuit pattern 175 from being oxidized.

In addition, the second solder resist layer 180 and the second external connection pad 176 may be formed in a step shape. As a result, when conductive bumps (not shown) are formed on the second external connection pad 176 later, the generation of the bridge phenomenon may be prevented.

The second solder resist layer 180 according to an exemplary embodiment of the present disclosure may be formed of a heat-resistant covering material.

The second solder resist layer 180 according to an exemplary embodiment of the present disclosure may be formed in order in which it is applied on the entire surface of the second insulating layer 160 and the second circuit layer 170 and is then patterned to expose the second external connection pad 176. Alternatively, the second solder resist layer 180 may be formed in a region except for the second external connection pad 176, such that it may be formed to be patterned simultaneously with the application.

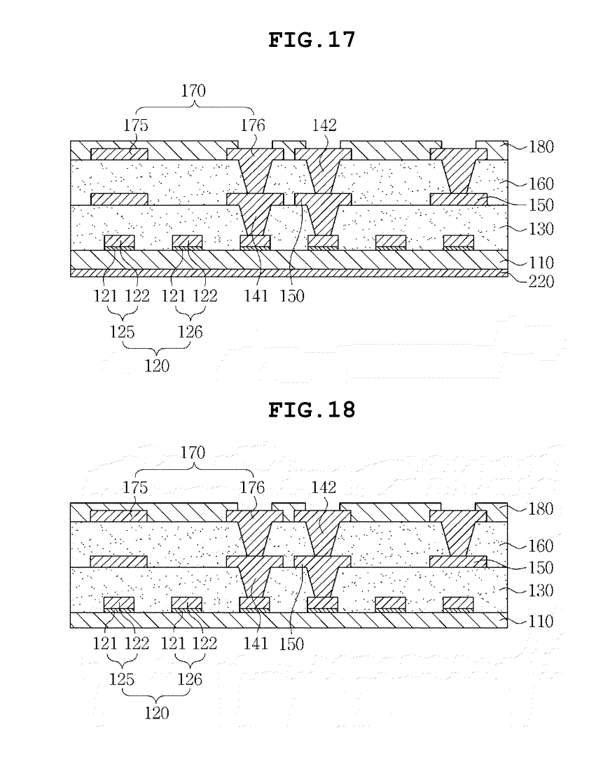

Referring to FIG. 17, the carrier member 210 (see FIG. 16) may be removed.

According to an exemplary embodiment of the present disclosure, the carrier member 210 (see FIG. 16) is removed, such that the bonding layer 220 formed below the first solder resist layer 110 may be exposed to the outside. The carrier member 210 (see FIG. 16) may be removed by a typical method of removing the carrier member which is already known.

Referring to FIG. 18, the bonding layer 220 (see FIG. 17) may be removed.

According to an exemplary embodiment of the present disclosure, the bonding layer 220 (see FIG. 17) may be removed by using an etching solution reacting to the material of the bonding layer 220 (see FIG. 17). Alternatively, the bonding layer 220 (see FIG. 17) may be removed by a mechanical polishing. By the removal of the bonding layer 220 (see FIG. 17) as described above, the first solder resist layer 110 may be exposed to the outside.

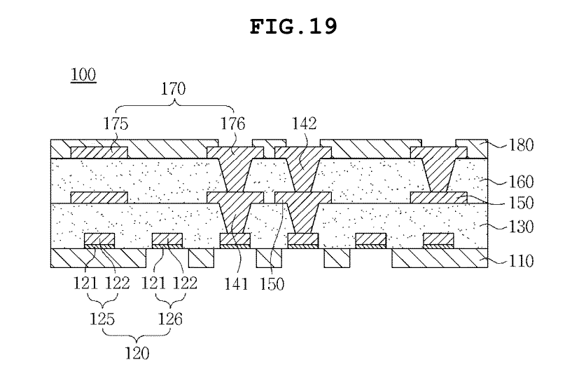

Referring to FIG. 19, the first solder resist layer 110 may be patterned.

According to an exemplary embodiment of the present disclosure, the first solder resist layer 110 may be patterned to expose the first external connection pad 126. The first solder resist layer 110 may be patterned by a typical method which is already known.

The method of manufacturing the printed circuit board according to an exemplary embodiment of the present disclosure may be performed in order of forming the first solder resist layer 110, forming the first circuit layer 120, and patterning the first solder resist layer 110. According to the above-mentioned operation order, the first circuit layer 120 may be buried in the first insulating layer 130, and the first circuit layer 120 and the first solder resist layer 110 may be formed in a step shape. That is, the first solder resist layer 110 may be formed to be more protruded than the first external connection pad 126 to serve as a barrier. As a result, when the conductive bumps are formed on the first external connection pad 126, the generation of the bridge phenomenon may be prevented.

As set forth above, the printed circuit board and the method of manufacturing the same may prevent the bridge phenomenon from being generated when the conductive bump is formed.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
an insulating layer;
a first circuit buried below the insulating layer and having a lower surface formed to be exposed from a lower surface of the insulating layer;
a second circuit layer formed on the insulating layer; and
a first solder resist layer formed below the insulating layer and the first circuit layer and formed to expose a portion of the first circuit layer.

2. The printed circuit board of claim 1, wherein the first circuit layer includes a seed layer and a metal layer formed on the seed layer, the seed layer having a lower surface exposed from the insulating layer.

3. The printed circuit board of claim 2, wherein the seed layer includes at least one of titanium (Ti), cobalt (co), and nickel (Ni).

4. The printed circuit board of claim 2, wherein the seed layer is a mixture of at least one of titanium (Ti), cobalt (co), and nickel (Ni), and copper (Cu).

5. The printed circuit board of claim 1, wherein the second circuit layer has a shape protruded from an upper surface of the insulating layer.

6. The printed circuit board of claim 1, wherein the insulating layer further includes an internal circuit layer formed between the first circuit layer and the second circuit layer and formed in one or more layers.

7. The printed circuit board of claim 1, further comprising a second solder resist layer formed on the insulating layer and the second circuit, and formed to expose a portion of the second circuit layer.

8. A method of manufacturing a printed circuit board, the method comprising:
preparing a carrier member;
forming a bonding layer on the carrier member;
forming a first solder resist layer on the bonding layer;
forming a seed layer on the first solder resist layer;
forming a patterned metal layer on the seed layer;
forming a circuit layer including the metal layer and the seed layer by removing the seed layer exposed by the metal layer;
an insulating layer formed on the first solder resist layer and burying the first circuit layer;
forming a second circuit layer on the insulating layer;
removing the carrier member and the bonding layer; and
patterning the first solder resist layer to expose a portion of the first circuit layer.

9. The method of claim 8, wherein the bonding layer is formed by a sputtering method.

10. The method of claim 8, wherein the bonding layer includes at least one of titanium (Ti), cobalt (co), and nickel (Ni).

11. The method of claim 8, wherein the bonding layer is a mixture of at least one of titanium (Ti), cobalt (co), and nickel (Ni), and copper (Cu).

12. The method of claim 8, wherein the seed layer is formed by a sputtering method.

13. The method of claim 8, wherein the seed layer includes at least one of titanium (Ti), cobalt (co), and nickel (Ni).

14. The method of claim 8, wherein the seed layer is a mixture of at least one of titanium (Ti), cobalt (co), and nickel (Ni), and copper (Cu).

15. The method of claim 8, wherein in the forming of the second circuit layer, the second circuit layer is protruded from an upper surface of the insulating layer.

16. The method of claim 8, further comprising, before the forming of the second circuit layer, forming an internal circuit layer of one or more layers in the insulating layer.

17. The method of claim 8, further comprising, after the forming of the second circuit layer, forming a second solder resist layer formed on the insulating layer and the second circuit layer.

18. The method of claim 17, further comprising, after the forming of the second solder resist layer, patterning the second solder resist layer to expose a portion of the second circuit layer.
